(19) United States
(12) Patent Application Publication
(10) Pub. No.: US 2026/0317941 A1
(43) Pub. Date: Oct. 15, 2026

(54) PLATING APPARATUS

(71) Applicant: EBARA CORPORATION, Tokyo (JP)

(72) Inventors: Masaya SEKI, Tokyo (JP); Masashi SHIMOYAMA, Tokyo (JP); Takahisa OKUZONO, Tokyo (JP); Ryosuke HIWATASHI, Tokyo (JP)

(21) Appl. No.: 18/726,368

(22) PCT Filed: Nov. 14, 2023
(86) PCT No.: PCT/JP2023/041002

§ 371 Date: Jul. 2, 2024

(51) Int. Cl. C25D 21/12; C25D 17/02; C25D 17/06; C25D 17/12

(52) U.S. Cl. CPC C25D 21/12; C25D 17/02; C25D 17/06; C25D 17/12

(57) ABSTRACT

To detect a disturbance in an electric field formed between an anode and a substrate. A plating apparatus (10) includes a plating tank (50), an anode (21), a substrate holder (40), an anode mask (70), a regulation plate (30), a measuring electrode (74), a reference electrode (75), and a measuring instrument (76). The plating tank (50) is for containing a plating solution (Q). The anode (21) is disposed in the plating tank (50). The substrate holder (40) is for holding a substrate (WF) having a surface to be plated (WF1) opposed to the anode (21). The anode mask (70) is disposed between the anode (21) and the substrate holder (40), has an anode opening (70a) that passes through a side of the anode (21) and a side of the substrate holder (40), and is configured to be able to adjust a size of the anode opening (70a). The regulation plate (30) is disposed between the anode mask (70) and the substrate holder (40). The measuring electrode (74) is disposed between the anode mask (70) and the regulation plate (30). The reference electrode (75) is disposed in the plating solution (Q) contained in the plating tank (50). The measuring instrument (76) is for measuring a voltage between the reference electrode (75) and the measuring electrode (74).

### TECHNICAL FIELD

This application relates to a plating apparatus.

### BACKGROUND ART

A Dip-type plating apparatus and a cup-type plating apparatus are known as one examples of an electroplating apparatus. Both have something in common in that a substrate (for example, a semiconductor wafer) is held in a substrate holder and immersed in a plating solution and a conductive film is deposited on a surface of the substrate by applying a voltage between the substrate (a cathode) and an anode. The two differ in a direction in which a surface to be plated of the substrate faces. The dip-type plating apparatus immerses the substrate in the plating solution such that the surface to be plated faces laterally, while the cup-type plating apparatus immerses the substrate in the plating solution such that the surface to be plated faces downward.

PTL 1 discloses a dip-type plating apparatus. This plating apparatus includes an anode mask for regulating an electric field between an anode and a substrate. The anode mask is a plate-shaped member disposed between the anode and a substrate holder, has in the center an opening through which a current flowing between the anode and the substrate passes, and is configured to be able to adjust the diameter of the opening.

### CITATION LIST

### Patent Literature

PTL 1: Japanese Patent No. 6335763

### SUMMARY OF INVENTION

### Technical Problem

It is not considered that the plating apparatus disclosed in PTL 1 detects a disturbance in the electric field formed between the anode and the substrate.

In other words, a part of the anode mask (for example, a member for adjusting the diameter of the opening of the anode mask) may deteriorate to be damaged due to a chemical change caused by the plating solution. When the part of the anode mask is damaged, the electric field between the anode and the substrate is disturbed, thus making it difficult to form a desired film-thickness distribution of plating on a surface to be plated. In addition to the anode mask, another member disposed in a plating tank may also be damaged due to the chemical change caused by the plating solution.

Furthermore, in the plating apparatus, the anode, the anode mask, and the substrate (the substrate holder) are required to be arranged in appropriate axis-aligned positions. However, when any of the members is misaligned, the electric field between the anode and the substrate is disturbed, thus making it difficult to form the desired plating film-thickness distribution.

Therefore, it is one object of this application to detect a disturbance in an electric field formed between an anode and a substrate.

### Solution to Problem

According to one embodiment, a plating apparatus is disclosed. The plating apparatus includes a plating tank, an anode, a substrate holder, an anode mask, an electric field regulating member, a measuring electrode, a reference electrode, and a measuring instrument. The plating tank is for containing a plating solution. The anode is disposed in the plating tank. The substrate holder is for holding a substrate having a surface to be plated opposed to the anode. The anode mask is disposed between the anode and the substrate holder, has an anode opening that passes through a side of the anode and a side of the substrate holder, and is configured to be able to adjust a size of the anode opening. The electric field regulating member is disposed between the anode mask and the substrate holder. The measuring electrode is disposed between the anode mask and the electric field regulating member. The reference electrode is disposed in the plating solution contained in the plating tank. The measuring instrument is for measuring a voltage between the reference electrode and the measuring electrode.

### BRIEF DESCRIPTION OF DRAWINGS

FIG. 1 is a cross-sectional view illustrating an overall configuration of a plating apparatus according to one embodiment.

FIG. 2 is a schematic front view of an anode mask according to the one embodiment.

FIG. 3 a vertical cross-sectional view of the anode mask according to the one embodiment.

FIG. 4 is a schematic front view of an anode mask according to one embodiment.

FIG. 5 is a schematic front view of an anode mask according to one embodiment.

FIG. 6 is a cross-sectional view illustrating an overall configuration of a plating apparatus according to one embodiment.

### DESCRIPTION OF EMBODIMENTS

The following describes embodiments of the present invention with reference to the drawings. In the drawings described later, identical reference numerals are assigned to identical or equivalent constituent elements, and therefore, such elements will not be described again.

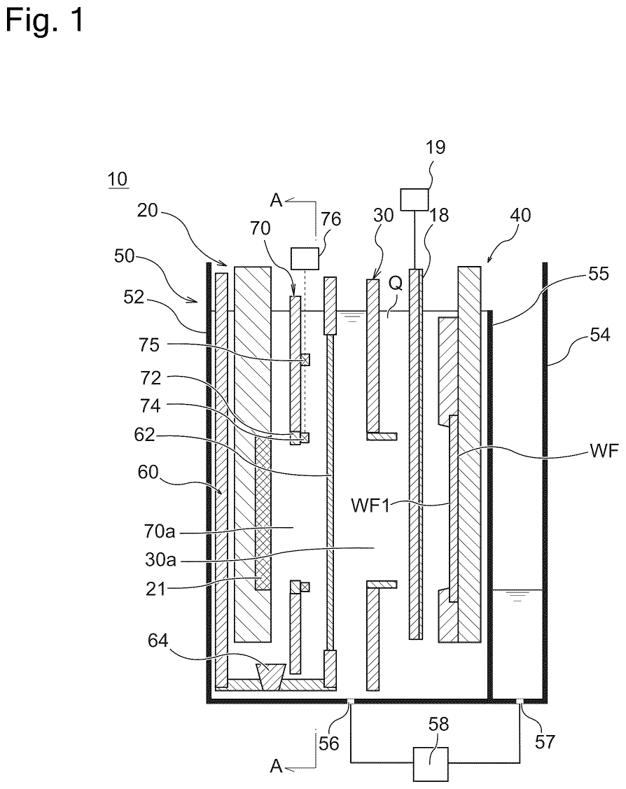

FIG. 1 is a cross-sectional view illustrating an overall configuration of a plating apparatus according to one embodiment. As illustrated in the figure, a plating apparatus 10 according to this embodiment includes an anode holder 20 configured to hold an anode 21, a substrate holder 40 configured to hold a substrate WF, and a plating tank 50 that houses the anode holder 20 and the substrate holder 40 inside. In this embodiment, the substrate WF is formed in a shape of a disc, and the anode 21 is formed in a shape of a disc corresponding to the shape of the substrate WF.

As illustrated in FIG. 1, the plating tank 50 includes a plating process tank 52 that contains a plating solution Q containing additives, a plating solution discharge tank 54 that receives and discharges the plating solution Q overflowing from the plating process tank 52, and a partition wall 55 disposed between the plating process tank 52 and the plating solution discharge tank 54.

The anode holder 20 holding the anode 21 and the substrate holder 40 holding the substrate WF are immersed in the plating solution Q in the plating process tank 52, and are set to be opposed to each other such that the anode 21 and a surface to be plated WF1 of the substrate WF are approximately parallel. In other words, the substrate holder 40 holds the substrate WF with the surface to be plated WF1 facing laterally. While the anode 21 and the substrate WF are immersed in the plating solution Q in the plating process tank 52, a voltage is applied to them. As a result, metal ions are reduced on the surface to be plated WF1 of the substrate WF, and a film is formed on the surface to be plated WF1.

The plating process tank 52 has a plating solution inlet 56 for supplying the plating solution Q to the inside of the tank. The plating solution discharge tank 54 has a plating solution discharge port 57 for discharging the plating solution Q that has overflowed from the plating process tank 52. The plating solution inlet 56 is disposed at a bottom of the plating process tank 52, and the plating solution discharge port 57 is disposed at a bottom of the plating solution discharge tank 54.

When the plating solution Q is supplied from the plating solution inlet 56 to the plating process tank 52, the plating solution Q overflows from the plating process tank 52 and flows over the partition wall 55 into the plating solution discharge tank 54. The plating solution Q that has flowed into the plating solution discharge tank 54 is discharged from the plating solution discharge port 57, and impurities are removed by a filter or the like of a plating solution circulating device 58. The plating solution Q from which the impurities have been removed is supplied to the plating process tank 52 via the plating solution inlet 56 by the plating solution circulating device 58.

The plating apparatus 10 includes an anode mask 70 for regulating an electric field between the anode 21 and the substrate WF. The anode mask 70 is an approximately plate-shaped member made of a dielectric material, for example, and is disposed on a front surface of the anode holder 20. Here, the front surface of the anode holder 20 refers to a surface on a side opposed to the substrate holder 40. In other words, the anode mask 70 is disposed between the anode 21 and the substrate holder 40. The anode mask 70 has an anode opening 70a in an approximately center portion thereof, which passes through a side of the anode 21 and a side of the substrate holder 40, in other words, through which a current flowing between the anode 21 and the substrate WF passes. The diameter of the anode opening 70a is preferred to be smaller than the diameter of the anode 21. The anode mask 70 is configured be able to adjust the diameter of the anode opening 70a. This point will be described below.

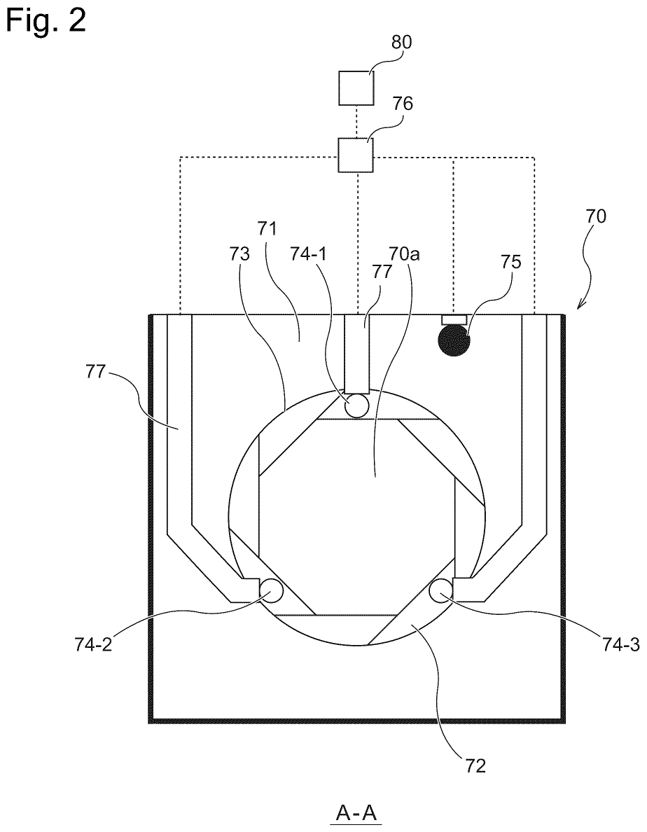

FIG. 2 is a schematic front view of the anode mask 70. FIG. 2 is a diagram viewed along arrows of the A-A line in FIG. 1. As illustrated in FIG. 2, the anode mask 70 includes a plate-shaped anode mask body 71 and an approximately annular edge 73 formed in the center of the anode mask body 71. The anode mask 70 includes a plurality of aperture blades 72 configured to be able to adjust the anode opening 70a. The aperture blades 72 are attached to the edge 73 and cooperate to define the anode opening 70a. Each of the aperture blades 72 expands or contracts the diameter of the anode opening 70a (adjusts the diameter of the anode opening 70a) using a structure similar to an aperture mechanism of a camera. The anode opening 70a of the anode mask 70 illustrated in FIG. 2 is formed in a non-circular shape (for example, a polygonal shape) by the aperture blades 72. In this case, the diameter of the anode opening 70a is the shortest distance between opposite sides of a polygon or the diameter of an inscribed circle. Alternatively, the diameter of the anode opening 70a can also be defined as the diameter of a circle having an area equivalent to the opening area.

Each of the aperture blades 72 expands or contracts the diameter of the anode opening 70a, for example, manually. Each of the aperture blades 72 may also be configured to be driven by air pressure or electric driving force.

Referring to FIG. 1, the plating apparatus 10 includes a regulation plate 30, which is one example of an electric field regulating member for regulating the electric field between the anode 21 and the substrate WF. The regulation plate 30 is an approximately plate-shaped member made of a dielectric material, for example, and is disposed between the anode mask 70 and the substrate holder 40 (the substrate WF). The regulation plate 30 has a regulation opening 30a that passes through the side of the anode 21 and the side of the substrate holder 40, in other words, through which the current flowing between the anode 21 and the substrate WF passes. The diameter of the regulation opening 30a is preferred to be smaller than the diameter of the substrate WF.

The regulation plate 30, similarly to the anode mask 70, may be configured to be able to adjust the diameter of the regulation opening 30a by aperture blades. However, the adjustment of the diameter of the regulation opening 30a is not limited to the aperture blades. For example, the diameter of the regulation opening 30a can be adjusted by attaching an elastic tube to an approximately annular edge and moving a fluid (a gas such as air or nitrogen, or a fluid such as water) in and out of an inner cavity of the elastic tube to expand/contract the elastic tube.

The regulation plate 30 is preferred to be closer to the substrate holder 40 than an intermediate position between the anode holder 20 and the substrate holder 40. The closer the regulation plate 30 is positioned to the substrate holder 40, the more accurately the film thickness at the periphery of the substrate WF can be controlled by adjusting the diameter of the regulation opening 30a of the regulation plate 30.

Between the regulation plate 30 and the substrate holder 40, a paddle 18 is disposed to agitate the plating solution Q close to the surface to be plated WF1 of the substrate WF. One end of the paddle 18 is fixed to a paddle driving device 19. The paddle 18 is moved along the surface to be plated WF1 of the substrate WF by the paddle driving device 19, thereby agitating the plating solution Q.

The plating apparatus 10 further includes a membrane box 60. The membrane box 60 is a box-shaped member for housing the anode holder 20 (the anode 21) and the anode mask 70 in the plating tank 50. The membrane box 60 includes a membrane 62 disposed between the anode mask 70 and the regulation plate 30. The membrane 62 is a membrane that divides an anode region where the anode 21 is disposed and a cathode region where the substrate WF is disposed. The membrane box 60 includes a plug 64 for draining the plating solution Q from the membrane box 60 when the membrane box 60 is elevated from the plating tank 50.

Next, an aspect in which the plating apparatus 10 detects disturbances in the electric field will be described. As illustrated in FIG. 2, the plating apparatus 10 includes a measuring electrode 74 (three measuring electrodes 74-1, 74-2, 74-3 in the embodiment of FIG. 2), a reference electrode 75, and a measuring instrument 76 that measures a voltage between the reference electrode 75 and the measuring electrode 74.

In the embodiment of FIG. 2, the measuring electrodes 74-1, 74-2, 74-3 are arranged on a surface of the substrate holder 40 side of the anode mask 70 at equal intervals (120° intervals) on a circumference of the anode opening 70a relative to its center. More specifically, the measuring electrodes 74-1, 74-2, 74-3 are disposed on surfaces of the substrate holder 40 side of the aperture blades 72. However, the measuring electrodes 74 are not limited to the arrangement aspect as in the embodiment of FIG. 2, and may be disposed between the anode mask 70 and the regulation plate 30 (the electric field regulating member). When there are a plurality of the measuring electrodes 74, the respective measuring electrodes 74 may be equally spaced on a circumference around a virtual axis connecting the center of the anode 21 and the center of the substrate WF. The number of measuring electrodes 74 may be singular.

The reference electrode 75 is disposed farther from the center of the anode mask 70 than the measuring electrodes 74-1, 74-2, 74-3 on the surface of the substrate holder 40 side of the anode mask 70. However, the reference electrode 75 is not limited to the arrangement aspect as in the embodiment of FIG. 2, and it is sufficient that it is disposed in the plating solution Q contained in the plating tank 50. The measuring electrode 74 and the reference electrode 75 are each connected to the measuring instrument 76 via a pattern wiring 77.

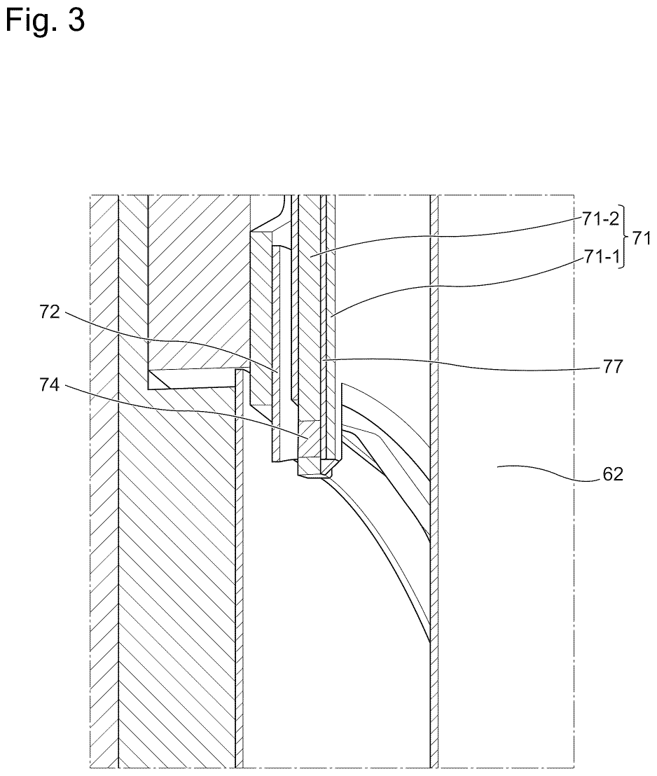

FIG. 3 is a perspective cross-sectional view of the anode mask 70 and the membrane 62 according to the one embodiment. As illustrated in FIG. 3, the anode mask body 71 includes a plate-shaped first anode mask body 71-1 and a plate-shaped second anode mask body 71-2. The first anode mask body 71-1 and the second anode mask body 71-2 are disposed to be spaced and opposed to each other. The pattern wiring 77 is disposed in a space between the first anode mask body 71-1 and the second anode mask body 71-2. The pattern wiring 77 can be configured by pattern forming copper foil on a substrate such as epoxy. The first anode mask body 71-1 and the second anode mask body 71-2 function as an encapsulant to prevent the plating solution Q from entering an interior space that houses the pattern wiring 77.

Since the measuring instrument 76 can measure the voltage of the measuring electrode 74 with respect to the reference electrode 75, the plating apparatus 10 can detect disturbances in the electric field formed between the anode 21 and the substrate WF. An example of the detection of the disturbances in the electric field will be described below.

Referring to FIG. 2, the plating apparatus 10 includes a detecting member 80 configured to detect damage of the anode mask 70 or the regulation plate 30 (the electric field regulating member) based on a temporal change of the voltage measured by the measuring instrument 76. That is, a part of the anode mask 70 (for example, the aperture blade 72 for adjusting the diameter of the anode opening) may deteriorate to be damaged due to a chemical change caused by the plating solution. When the part of the anode mask is damaged, the electric field between the anode and the substrate is disturbed, thus making it difficult to form a desired film-thickness distribution of plating on the surface to be plated. In addition to the anode mask 70, the regulation plate 30 may also be damaged due to the chemical change caused by the plating solution.

In contrast, the detecting member 80 detects that the voltage of at least one of the measuring electrodes 74-1, 74-2, 74-3 has changed with respect to a normal state based on the temporal change of the voltage measured by the measuring instrument 76. For example, when the aperture blade 72 disposed close to the measuring electrode 74-1 is damaged, the voltage of the measuring electrode 74-1 changes with respect to the normal state. When the detecting member 80 detects that the voltage of the measuring electrode 74-1 has changed with respect to the normal state, it can issue an alarm indicating a possibility of damage to the aperture blade 72 disposed close to the measuring electrode 74-1. The detecting member 80 can also issue an alarm and stop the operation of the plating apparatus 10.

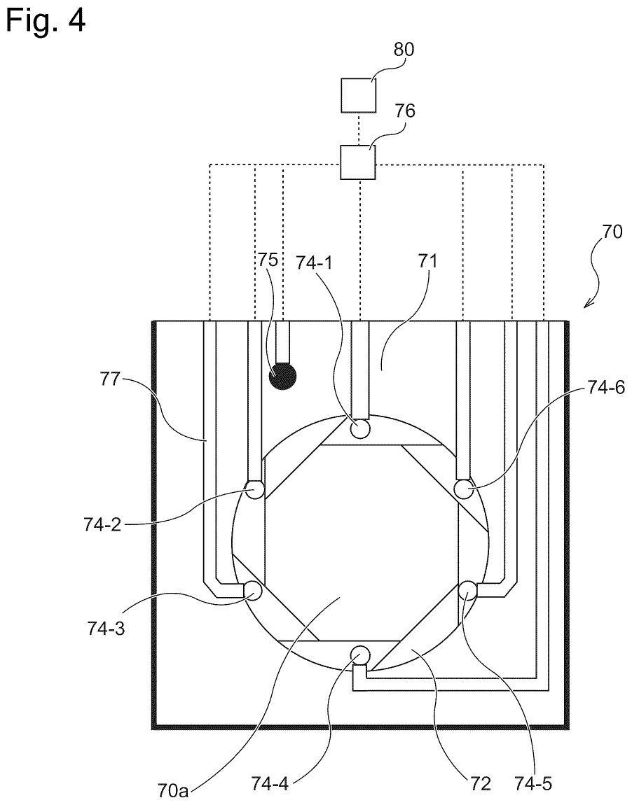

FIG. 4 is a schematic front view of an anode mask according to one embodiment. As illustrated in FIG. 4, the plating apparatus 10 may have six measuring electrodes 74-1 to 74-6. In this case, the measuring electrodes 74-1 to 74-6 are arranged on the surface of the substrate holder 40 side of the anode mask 70 at equal intervals (60° intervals) on the circumference of the anode opening 70a relative to its center.

The detecting member 80 is configured to detect damage to the anode mask 70 or the regulation plate 30 (the electric field regulating member) based on the temporal change of the voltage measured by the measuring instrument 76 for each of the measuring electrodes 74-1 through 74-6. Increasing the number of measuring electrodes 74 as in this embodiment allows more specifically detecting a place where a disturbance is occurring in the electric field formed between the anode 21 and the substrate WF. As a result, for example, when damage occurs in the aperture blade 72, a location where the damage occurs can be more specifically identified.

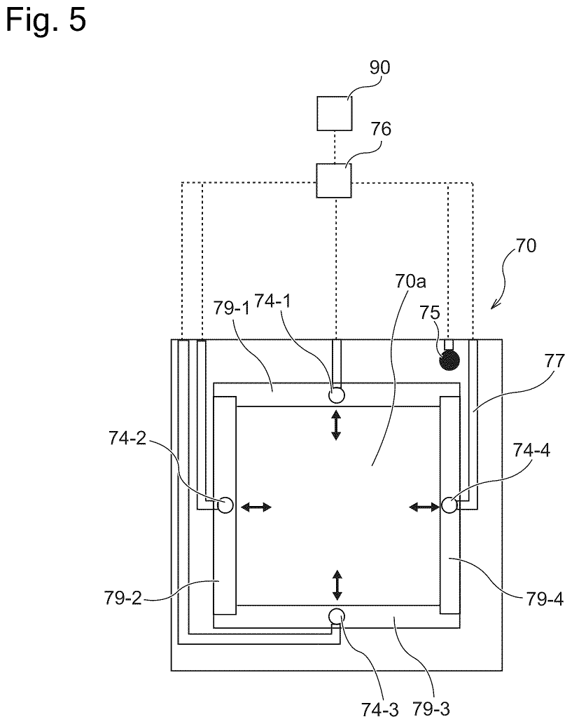

FIG. 5 is a schematic front view of an anode mask according to one embodiment. This embodiment is an embodiment of a plating apparatus that performs a plating process on the substrate WF formed in a rectangular shape. As illustrated in FIG. 5, the anode opening 70a is formed in a rectangular shape corresponding to a shape of the rectangular substrate WF.

As illustrated in FIG. 5, the anode mask 70 includes a plurality of shielding members 79 (shielding members 79-1, 79-2, 79-3, 79-4) disposed on respective sides of the rectangular anode opening 70a. Each of the shielding members 79 is movable in a direction toward and away from the center of the anode opening 70a. As illustrated in FIG. 5, the plating apparatus 10 includes a plurality of (four) measuring electrodes 74-1, 74-2, 74-3, 74-4, each of which is arranged for each side of the rectangular anode opening 70a

The plating apparatus 10 includes an opening adjustment member 90 configured to move the shielding member 79 based on the voltages of the plurality of measuring electrodes measured by the measuring instrument 76. The opening adjustment member 90 can adjust the anode opening 70a when the anode 21, the anode mask 70, and the substrate WF (the substrate holder 40) are misaligned with an axis.

In other words, the anode 21, the anode mask 70, and the substrate WF (the substrate holder 40) are required to be disposed in the proper position and mutually aligned with the axis. However, when any of the members is misaligned, the electric field between the anode and the substrate is disturbed, thus making it difficult to form the desired plating film-thickness distribution.

In contrast, the opening adjustment member 90 compares values of the voltages of the measuring electrodes on opposite sides of the anode opening 70a, and based on the comparison results, the position of the anode opening 70a is adjusted by moving the shielding members 79-1, 79-2, 79-3, 79-4. For example, assume that the substrate holder 40 is disposed in a lower position than its appropriate position. In this case, the electric field between the anode and the substrate is disturbed, and the voltage of the measuring electrode 74-3 can be higher when the voltage of the measuring electrode 74-1 and the voltage of the measuring electrode 74-3 are compared. Based on the result of this comparison, the opening adjustment member 90 moves the anode opening 70a downward by moving the shielding members 79-1, 79-3 downward. The opening adjustment member 90 can move the shielding members 79-1, 79-3 downward until the voltage of the measuring electrode 74-1 becomes equal to the voltage of the measuring electrode 74-3. As a result, the disturbance in the electric field between the anode and the substrate is suppressed, thus making it easy to form the desired plating film-thickness distribution.

In the above embodiments, a dip-type plating apparatus, in which the substrate WF is immersed in the plating solution such that the surface to be plated WF1 faces laterally, has been described as an example, but the present invention is not limited to this. The present invention can also be applied to a cup-type plating apparatus, in which the substrate WF is immersed in the plating solution such that the surface to be plated WF1 faces downward. This point will be described below.

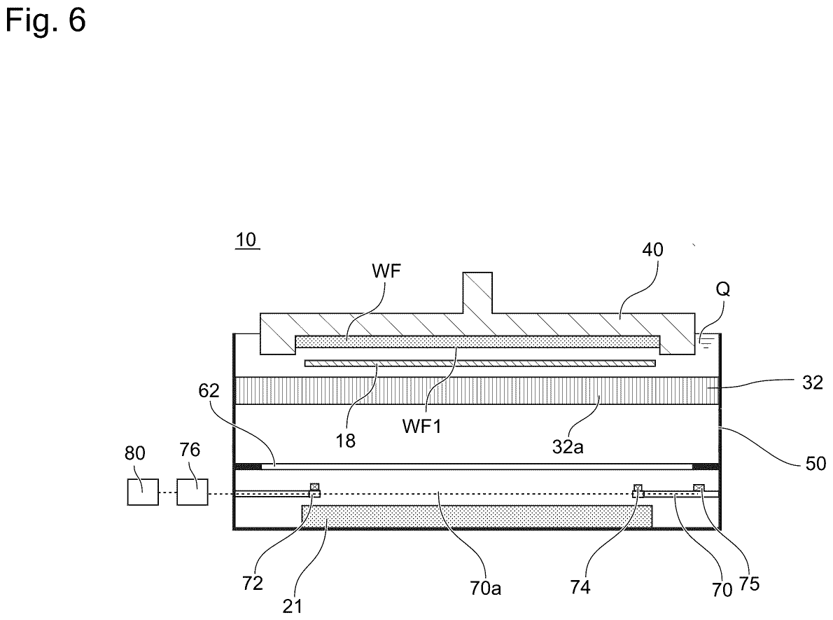

FIG. 6 is a cross-sectional view illustrating an overall configuration of a plating apparatus according to one embodiment. Identical reference numerals are assigned to members having the same functions as those in the above embodiments, and therefore, such members will not be described again.

As illustrated in FIG. 6, the substrate holder 40 is configured to hold the substrate WF with the surface to be plated WF1 facing downward. The plating apparatus 10 includes an ionically resistive element 32 (the electric field regulating member), which is disposed between the anode mask 70 and the substrate holder 40 and has a plurality of openings 32a that pass through the side of the anode 21 and the side of the substrate holder 40. The ionically resistive element 32 can be a punched plate with a plurality of punched openings as one example, but it is not limited to this.

With this embodiment, similarly to the above embodiments, the plating apparatus 10 can detect a disturbance in the electric field formed between the anode 21 and the substrate WF since the plating apparatus 10 can measure the voltage of the measuring electrode 74 with respect to the reference electrode 75 by the measuring instrument 76. The plating apparatus 10 also includes the detecting member 80 configured to detect damage to the anode mask 70 or the ionically resistive element 32 (the electric field regulating member) based on the temporal change of the voltage measured by the measuring instrument 76. When the detecting member 80 detects that the voltage of the measuring electrode 74 has changed with respect to the normal state, it can issue an alarm indicating the possibility of damage to the aperture blade 72 disposed close to the measuring electrode 74. The detecting member 80 can also issue an alarm and stop the operation of the plating apparatus 10.

While several embodiments of the present invention have been described above, the above-described embodiments of the invention are intended to facilitate understanding of the present invention and are not intended to limit the present invention. The present invention can be changed or improved without departing from the gist thereof, and it is a matter of course that the equivalents of the present invention are included in the present invention. To the extent that at least part of the above-described problems can be solved, or to the extent that at least part of the effect is achieved, any combination or omission of each component described in the claims and the specification is possible.

This application discloses, as one embodiment, a plating apparatus including a plating tank, an anode, a substrate holder, an anode mask, an electric field regulating member, a measuring electrode, a reference electrode, and a measuring instrument. The plating tank is for containing a plating solution. The anode is disposed in the plating tank. The substrate holder is for holding a substrate having a surface to be plated opposed to the anode. The anode mask is disposed between the anode and the substrate holder, has an anode opening that passes through a side of the anode and a side of the substrate holder, and is configured to be able to adjust a size of the anode opening. The electric field regulating member is disposed between the anode mask and the substrate holder. The measuring electrode is disposed between the anode mask and the electric field regulating member. The reference electrode is disposed in the plating solution contained in the plating tank. The measuring instrument is for measuring a voltage between the reference electrode and the measuring electrode.

Furthermore, this application discloses, as one embodiment, the plating apparatus in which the measuring electrodes include a plurality of measuring electrodes equally spaced on a circumference around a virtual axis connecting a center of the anode and a center of the substrate.

Furthermore, this application discloses, as one embodiment, the plating apparatus in which the plurality of measuring electrodes are disposed on a surface on the side of the substrate holder of the anode mask.

Furthermore, this application discloses, as one embodiment, the plating apparatus further including a detecting member configured to detect damage to the anode mask or the electric field regulating member based on a temporal change of the voltage measured by the measuring instrument.

Furthermore, this application discloses, as one embodiment, the plating apparatus in which the anode opening is formed in a rectangular shape corresponding to a shape of a rectangular substrate held in the substrate holder, the plurality of measuring electrodes are each disposed for each side of a rectangular anode opening, and the anode mask includes a plurality of shielding members disposed on respective sides of the rectangular anode opening. The plating apparatus further includes an opening adjustment member configured to move the plurality of shielding members in a direction toward or away from a center of the anode opening based on the voltage measured by the measuring instrument.

Furthermore, this application discloses, as one embodiment, the plating apparatus in which the substrate holder is configured to hold the substrate with the surface to be plated facing laterally, and the electric field regulating member includes a regulation plate with a single regulation opening passing through the side of the anode and the side of the substrate holder.

Furthermore, this application discloses, as one embodiment, the plating apparatus in which the substrate holder is configured to hold the substrate with the surface to be plated facing downward, and the electric field regulating member includes an ionically resistive element with a plurality of openings passing through the side of the anode and the side of the substrate holder.

### REFERENCE SIGNS LIST

10 . . . plating apparatus
21 . . . anode
30 . . . regulation plate
30a . . . regulation opening
32 . . . ionically resistive element
32a . . . opening
40 . . . substrate holder
50 . . . plating tank
70 . . . anode mask
70a . . . anode opening
74 . . . measuring electrode
75 . . . reference electrode
76 . . . measuring instrument
79 . . . shielding member
80 . . . detecting member
90 . . . opening adjustment member
Q . . . plating solution
WF . . . substrate
WF1 . . . surface to be plated

1. A plating apparatus comprising:
a plating tank for containing a plating solution;
an anode disposed in the plating tank;
a substrate holder for holding a substrate having a surface to be plated opposed to the anode;
an anode mask disposed between the anode and the substrate holder, having an anode opening that passes through a side of the anode and a side of the substrate holder, and configured to be able to adjust a size of the anode opening;
an electric field regulating member disposed between the anode mask and the substrate holder;
a measuring electrode disposed between the anode mask and the electric field regulating member;
a reference electrode disposed in the plating solution contained in the plating tank; and
a measuring instrument for measuring a voltage between the reference electrode and the measuring electrode.

2. The plating apparatus according to claim 1, wherein
the measuring electrodes include a plurality of measuring electrodes equally spaced on a circumference around a virtual axis connecting a center of the anode and a center of the substrate.

3. The plating apparatus according to claim 2, wherein
the plurality of measuring electrodes are disposed on a surface on the side of the substrate holder of the anode mask.

4. The plating apparatus according to claim 1, further comprising
a detecting member configured to detect damage to the anode mask or the electric field regulating member based on a temporal change of the voltage measured by the measuring instrument.

5. The plating apparatus according to claim 2, wherein
the anode opening is formed in a rectangular shape corresponding to a shape of a rectangular substrate held in the substrate holder,
the plurality of measuring electrodes are each disposed for each side of a rectangular anode opening,
the anode mask includes a plurality of shielding members disposed on respective sides of the rectangular anode opening, and
the plating apparatus further includes an opening adjustment member configured to move the plurality of shielding members in a direction toward or away from a center of the anode opening based on the voltage measured by the measuring instrument.

6. The plating apparatus according to claim 1, wherein
the substrate holder is configured to hold the substrate with the surface to be plated facing laterally, and
the electric field regulating member includes a regulation plate with a single regulation opening passing through the side of the anode and the side of the substrate holder.

7. The plating apparatus according to claim 1, wherein
the substrate holder is configured to hold the substrate with the surface to be plated facing downward, and
the electric field regulating member includes an ionically resistive element with a plurality of openings passing through the side of the anode and the side of the substrate holder.
